(19) United States
(12) Patent Application Publication
(10) Pub. No.: US 2012/0146163 A1
(43) Pub. Date: Jun. 14, 2012

(54) MICROPHONE PACKAGE STRUCTURE AND METHOD FOR FABRICATING THE SAME

(75) Inventors: Tzong-Che Ho, Hsinchu City (TW); Chin-Fu Kuo, Tainan County (TW); Hsin-Li Lee, Hsinchu County (TW); Yao-Jung Lee, Tainan County (TW); Li-Chi Pan, Hsinchu County (TW)

(73) Assignee: Industrial Technology Research Institute, Hsinchu (TW)

(21) Appl. No.: 13/206,466

(22) Filed: Aug. 9, 2011

(30) Foreign Application Priority Data
Dec. 8, 2010 (TW) TW99142760

(51) Int. Cl. H01L 29/84; H01L 21/30

(52) U.S. Cl. 257/416; 438/53; 257/E29.324; 257/E21.211

(57) ABSTRACT

A microphone package structure is provided, including an integrated circuit (IC) structure and a microphone structure disposed thereover and electrically connected therewith. The IC structure includes a first semiconductor substrate with opposite first and second surfaces, and a first through hole disposed in and through the first semiconductor substrate. The microphone structure includes: a second semiconductor substrate with opposite third and fourth surfaces, wherein the third surface faces to the second surface of the first semiconductor substrate; a second through hole disposed in and through the second semiconductor substrate; an acoustic sensing device embedded in the second through hole and adjacent to the third surface; and a sealing layer disposed over the fourth surface of the second semiconductor substrate, defining a back chamber with the sealing layer, wherein the first through hole allows acoustic pressure waves to penetrate and pass therethrough to the acoustic sensing device.

### CROSS REFERENCE TO RELATED APPLICATIONS

This Application claims priority of Taiwan Patent Application No. 99142760, filed on Dec. 8, 2010, the entirety of which is incorporated by reference herein.

### BACKGROUND

1. Technical Field

The present disclosure relates to microphone devices and in particular to a microphone package structure and a method for fabricating the same.

2. Description of the Related Art

With the personalization and popularization of global communications devices, mobile phone usage has tremendously increased. Due to increasing video and audio function demands for practical applications, an additional microphone is provided in a mobile phone for video functions in addition to the essential microphone for communications functions. Thus, demand for microphones has increased.

Microphone devices fabricated by microelectromechanical system (MEMS) techniques have features such as being thin and small, and the ability to be fabricated by a reflow method to perform surface adhesion processes so that packaging costs thereof may be reduced. Thus, MEMS type microphone devices have gradually replaced the conventional electret condenser (ECM) type microphones in modern mobile phones.

Following are several disclosures concerning fabricating a microphone device by microelectromechanical system (MEMS) technology.

US Pat. Publication No. 2010/0052082 discloses a microelectromechanical system (MEMS) packaging structure, including a system-on-chip (SOC) chip having MEMS devices and circuits formed over a same substrate, wherein a packaging substrate comprising a chamber is disposed under the SOC chip. In this packaging structure, through silicon vias (TSVs) are needed for electrical connections.

US Pat. Publication No. 2010/0052082 discloses a microelectromechanical system (MEMS) microphone module, comprising a three-layer stacked structure of an integrated circuit (IC) chip, a microphone chip and a cover. The IC chip further comprises pads and vias in addition to circuits therein, and the microphone chip further comprises a back chamber, pads and vias in addition to a microphone device.

### SUMMARY

An exemplary microphone package structure, comprises an integrated circuit (IC) structure and a microphone structure disposed thereover and electrically connected therewith. The IC structure comprises a first semiconductor substrate with opposite first and second surfaces, and a first through hole disposed in and through the first semiconductor substrate. The microphone structure comprises: a second semiconductor substrate with opposite third and fourth surfaces, wherein the third surface faces to the second surface of the first semiconductor substrate; a second through hole disposed in and through the second semiconductor substrate; an acoustic sensing device embedded in the second through hole and adjacent to the third surface; and a sealing layer disposed over the fourth surface of the second semiconductor substrate, defining a back chamber with the sealing layer, wherein the first through hole allows acoustic pressure waves to penetrate and pass therethrough to the acoustic sensing device.

An exemplary method for fabricating a microphone package structure, comprises: providing an integrated circuit (IC) structure; providing a microphone structure thereover and electrically connected therewith; and performing a bonding process to bond first bonding pads of the IC structure with second bonding pads of the microphone structure, thereby forming the microphone package structure. The IC structure further comprises a first semiconductor substrate with opposite first and second surfaces; and one or a plurality of first through holes separately disposed in and through the first semiconductor substrate. The microphone structure further comprises: a second semiconductor substrate with opposite third and fourth surfaces, wherein the third surface faces to the second surface of the first semiconductor substrate; a second through hole disposed in and through the second semiconductor substrate; an acoustic sensing device embedded in the second through hole and adjacent to the third surface; and a sealing layer disposed over the fourth surface of the second semiconductor substrate, defining a back chamber with the sealing layer.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIGS. 1-6 are schematic diagrams showing a method for fabricating a microphone package structure according to an exemplary embodiment of the disclosure;

FIG. 7 is a schematic diagram showing a microphone package structure according to an exemplary embodiment of the disclosure; and

FIG. 8 is a schematic diagram showing a microphone package structure according to another exemplary embodiment of the disclosure.

### DETAILED DESCRIPTION

The following description is made for the purpose of illustrating the general principles of the disclosure and should not be taken in a limiting sense. The scope of the disclosure is best determined by reference to the appended claims.

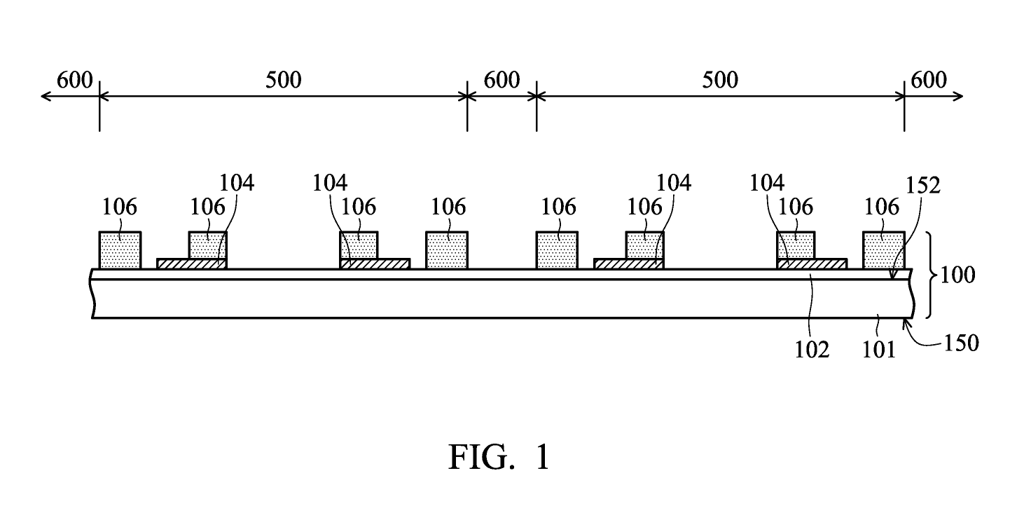

FIGS. 1-6 are schematic diagrams showing a method for fabricating a microphone package structure according to an exemplary embodiment of the disclosure, wherein a microphone device is fabricated by a microelectromechanical system (MEMS) technique.

In FIG. 1, an integrated circuit (IC) structure 100 is first provided, comprising a semiconductor substrate 101, a dielectric layer 102, a plurality of conductive layers 104, and a plurality of bonding pads 106 formed over the semiconductor substrate 101. Herein, the semiconductor substrate 101 is an un-diced substrate, for example a semiconductor wafer made of a semiconductor material such as silicon or silicon germanium. In addition, for the purpose of simplicity, the semiconductor substrate 101 in FIG. 1 is illustrated as a flat substrate. The semiconductor substrate 101, however, can be further processed to form active devices such as transistors or diodes, passive devices such as capacitor or resistors, or other components such as conductive lines, vias or contacts therein and/or thereover, thereby forming an integrated circuit with a predetermined function over the semiconductor substrate 101. In this embodiment, the semiconductor substrate 101 has opposite surfaces 150 and 152, wherein the surface 152 is an active surface so that active devices, passive device, other components, the dielectric layer 102, the conductive layer 104, and the bonding pads 106 disposed thereon, can be thus disposed thereover, and there is no component formed over the surface 150 of the semiconductor substrate 101.

Still referring to FIG. 1, two device regions 500 and a plurality of scribe line regions 600 between and beyond the device regions 500 are defined over the IC structure 100, and the dielectric layer 102, the conductive layer 104, and the bonding pads 106 can be disposed over the surface 152 of the semiconductor substrate 101 in each of the device regions 500 according to a similar configuration. It is noted that a greater amount of device regions 500 and scribe line regions 600 can be disposed over the IC structures 100, but is not limited to that illustrated in FIG. 1.

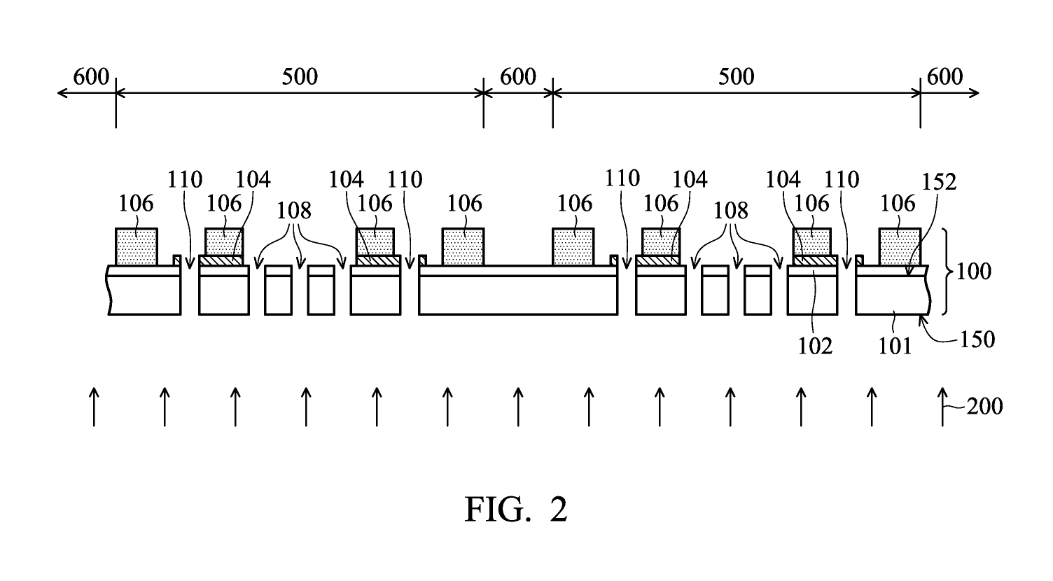

In. FIG. 2, an etching process 200 is performed from the surface 150 of the semiconductor substrate 101 to penetrate portions of the semiconductor substrate 101, the dielectric layer 102 and the conductive layer 104, thereby forming a plurality of through holes 108 and 110, wherein the through holes 108 are formed through the semiconductor substrate 101 and the dielectric layer 102, and the through holes 110 are formed through the semiconductor substrate 100, the dielectric layer 102, and the conductive layer 104. In one embodiment, the etching process 200 can be, for example, a deep reactive ion etching (DRIE) process.

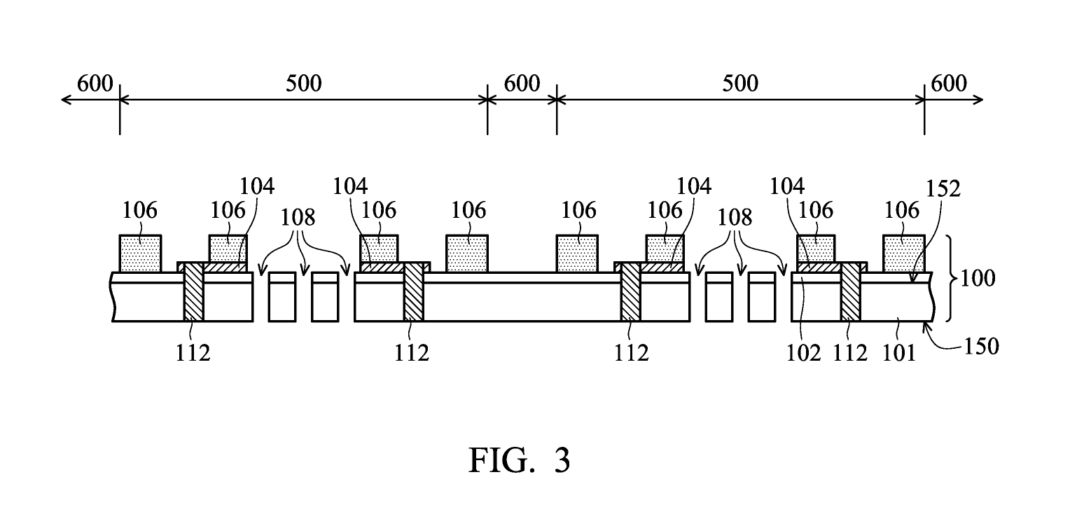

In FIG. 3, a deposition process (not shown) is performed to form an insulating layer (not shown) over a surface of the through holes 110, and then the through holes 110 are filled with conductive materials, thereby forming conductive contacts 112. As shown in FIG. 3, the conductive contacts 112 physically contact sidewalls of the conductive layer 104 which are exposed by the semiconductor substrate 101 and the conductive layer 104.

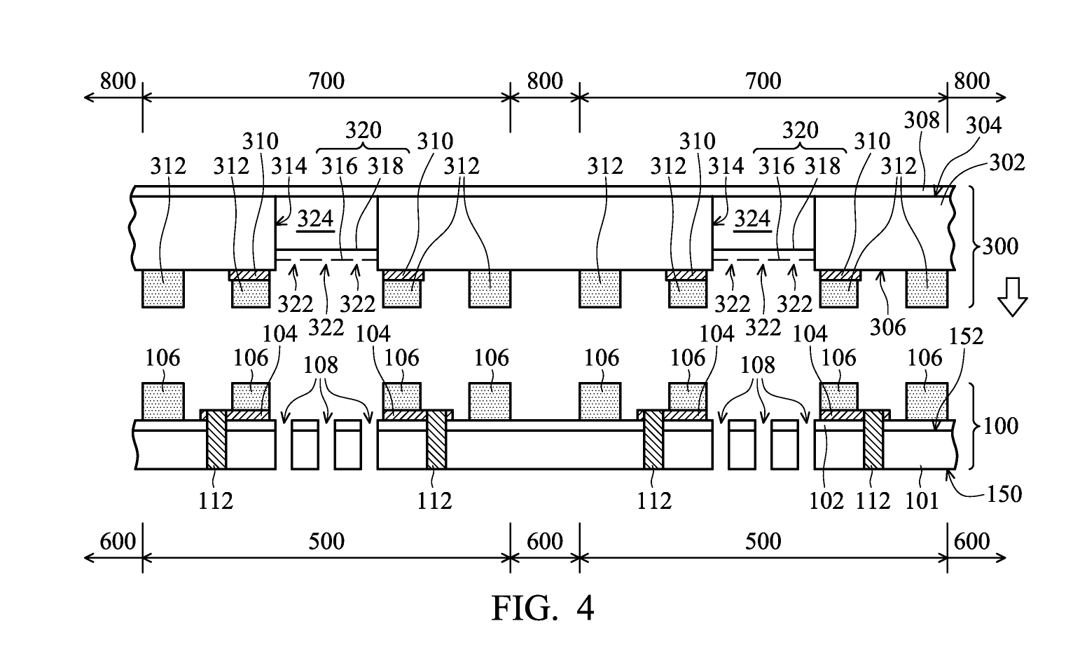

In FIG. 4, a substantially fabricated microphone structure 300 is provided, such as a microphone structure processed by a microelectromechanical system (MEMS) technique. The microphone structure comprises a semiconductor substrate 302, a sealing layer 308, a plurality of conductive layers 308, a plurality of bonding pads 312, a plurality of through holes 314 penetrating the semiconductor substrate 302, and a plurality of acoustic sensing devices 320. Two device regions 700 and a plurality of scribe line regions 800 between and beyond the device regions 700 are illustrated over the microphone structure 300, and the conductive layers 310, the bonding pads 312, the through holes 314, and the acoustic sensing devices 320 can be disposed over or in the semiconductor substrate 302 in each of the device regions 700 according to a similar configuration. The sealing layer 308 may comprise a layer of conductive polymer such as conductive polyimide, or a metal such as iron, nickel, or tin, thereby providing suitable EMI shielding functions to the microphone structure 300. It is understood that a greater amount of device regions 700 and scribe line regions 800 can be further provided over the microphone structure 300, but is not limited to that illustrated in FIG. 4. In this embodiment, the semiconductor substrate 302 is an un-diced substrate, for example a semiconductor wafer made of silicon, having opposite surfaces 304 and 306. In this embodiment, for the purpose of simplicity, the semiconductor substrate 302 in FIG. 4 is illustrated as a flat substrate. However, it can be further processed by suitable microelectromechanical system (MEMS) techniques, thereby forming additional layers such as insulating layers, dielectric layers, or conductive layers thereover or therein such that a conductive circuit for electrical connection is formed over the semiconductor substrate 302.

Still referring to FIG. 4, in this embodiment, the surface 306 of the semiconductor substrate 302 faces to the surface 152 of the semiconductor substrate 101, and the sealing layer 308 is disposed over the surface 304 of the semiconductor substrate 302, thereby sealing the through holes 314. The conductive layers 310 and the bonding pads 312 are disposed at suitable places over the surface 306 of the semiconductor substrate 306 to provide suitable electrical connections. The sealing layer 308 and the through holes 314 disposed over the semiconductor substrate 302 define back chambers 324 for the microphone structure. Each of the acoustic sensing devices 320 comprises a membrane 318 and a back plate 316 with a plurality of acoustic holes 322 formed therein. An air gap (not shown) is provided between the membrane 318 and the back plate 316. The back plate 316 and the membrane 318 partially extend into a layer (not shown) formed over the semiconductor substrate 302. Thus, the back plate 316 and the membrane 318 hang over separating portions of the semiconductor substrate 302 at a place having relatively fixed spaces. The back plate 316 and the membrane 318 may comprise conductive materials such as metal or doped semiconductor materials. The back plate 316 and the membrane 318 form a signal conditioning circuit (not shown) which is electrically connected in the microphone structure 300. A plurality of bonding pads 312 are formed over the microphone structure 300 to provide electrical connections to the signal conditioning circuit.

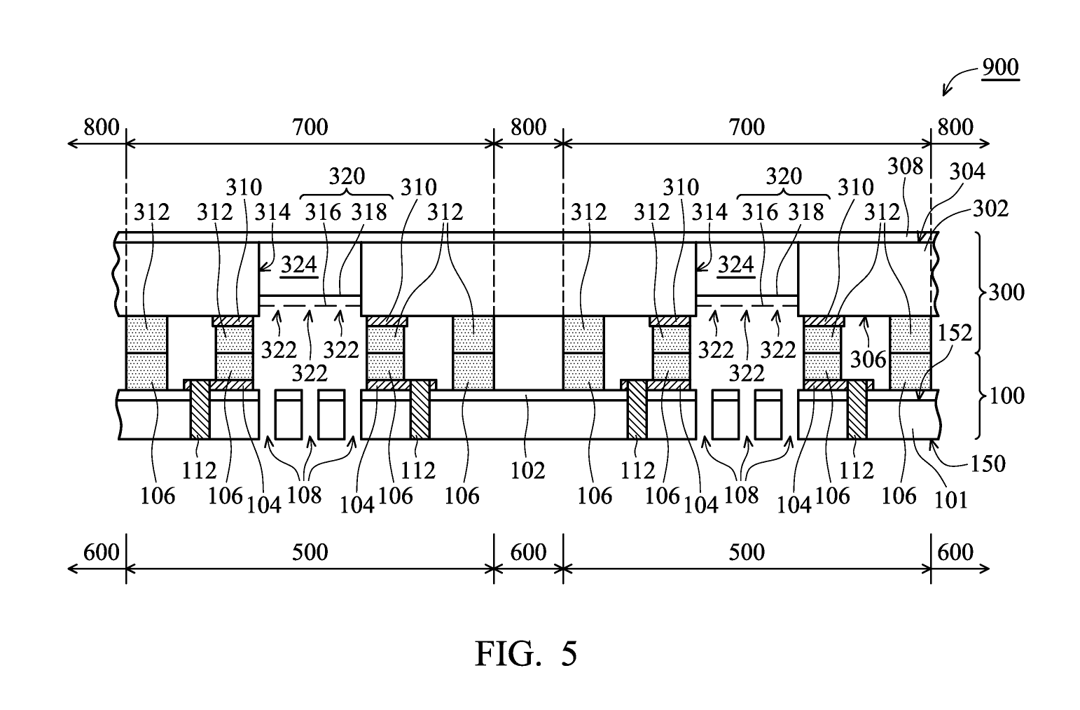

Next, the microphone structure 300 and the IC structure 100 are bonded to each other by a method such as a conductive glue adhesion or an eutectic welding adhesion bonding process, and the bonding pads 312 over the microphone structure 300 are respectively aligned and contacted with one of the bonding pads 106 formed over the IC structure 100, thereby forming a wafer-level microphone package structure 900 as shown in FIG. 5.

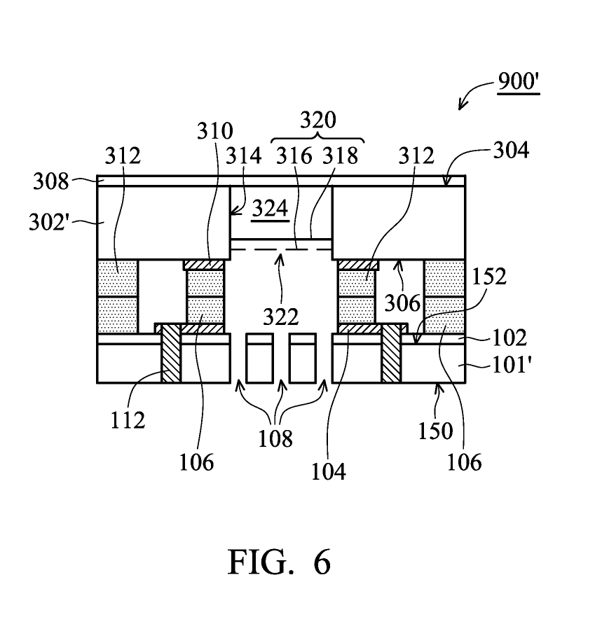

Note that fabrication costs and complexity of the microphone package structure 900 shown in FIG. 5 is reduced, as the wafer-level fabrication method shown in FIGS. 1-4 may be used for a single fabrication process, wherein only two substrate layers need to be stacked, to provide a large amount of microphone package structures (illustrated as the microphone package structure 900′ shown in FIGS. 6-8).

In FIG. 5, a dicing process (not shown) is then performed to the scribe line regions 600 or 800 for dicing the wafer-level microphone package structure 900 shown in FIG. 5 into a plurality of chip-level microphone package structures 900′, as shown in FIG. 6. After dicing of the microphone package structure 900, the semiconductor substrate 101 and 302 shown as the original microphone package structure 900 shown in FIG. 5, is now titled as 101′ and 302′, respectively.

Thus, as shown in FIG. 6, an exemplary microphone package structure 900′ is provided, comprising an integrated circuit (IC) structure and a microphone structure disposed thereover and electrically connected therewith.

The above IC structure comprises a first semiconductor substrate (e.g. the semiconductor substrate 101′) with opposite first and second surfaces (e.g. the surfaces 150 and 150), and one or a plurality of first through holes (e.g. the through holes 108) separately disposed in and through the first semiconductor substrate. The microphone structure comprises: a second semiconductor substrate (e.g. the semiconductor substrate 302′) with opposite third and fourth surfaces (e.g. the surfaces 306 and 304), wherein the third surface faces to the second surface of the first semiconductor substrate; a second through hole (e.g. the through hole 314) disposed in and through the second semiconductor substrate; an acoustic sensing device (e.g. the acoustic sensing device 320) embedded in the second through hole and adjacent to the third surface; and a sealing layer (e.g. the sealing layer 308) disposed over the fourth surface of the second semiconductor substrate, defining a back chamber (e.g. the back chamber 324) with the sealing layer, wherein the first through hole allows acoustic pressure waves to penetrate and pass therethrough to the acoustic sensing device.

During operation, the through holes 108 inside of the semiconductor substrate 101′ function as acoustic openings for receiving acoustic pressure waves from the surrounding environment, and the acoustic pressure waves thus penetrates the acoustic openings 322 and release acoustic pressure on the membrane 318 while the acoustic pressure waves strike the acoustic sensing device 320 comprising the back plate 316 and the membrane 318. Thus, in such acoustic pressure situations, the membrane 318 vibrates and electrical signals are generated according to migration of the acoustic pressure.

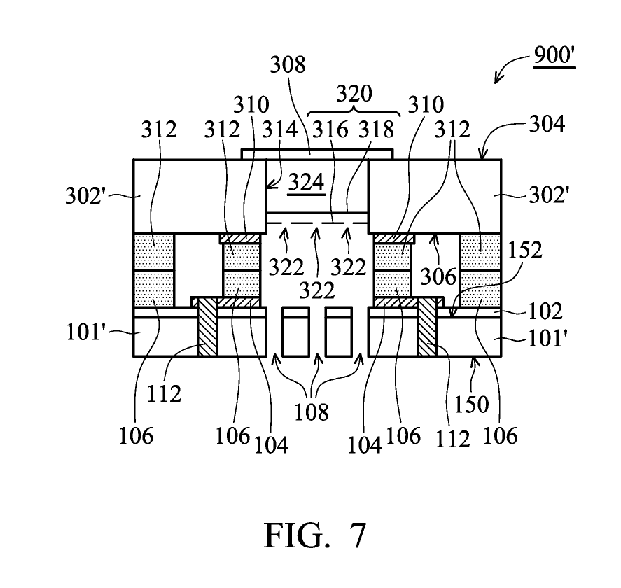

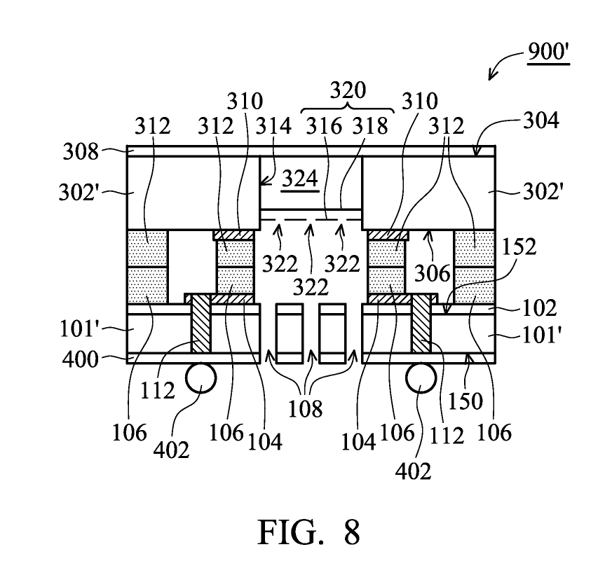

FIGS. 7 and 8 are schematic diagrams showing a microphone packaging structure 900′ according to other embodiments of the disclosure which modified from the microphone packaging structure 900′ shown in FIG. 6.

As shown in FIG. 7, the sealing layer 308 formed over the surface 304 of the semiconductor substrate 302′ in the microphone package structure 900′ is patterned to merely cover the through hole 314 and portions of the semiconductor substrate 302′ adjacent thereto, and the sealing layer 308 does not entirely cover the surface 304 of the semiconductor substrate 302′. In addition, as shown in FIG. 8, a conductive layer 400 and a plurality of conductive bumps 402 are further disposed over the surface 150 of the semiconductor substrate 101′ of the microphone packaging structure 900′, through the use of the conductive layer 400 and the conductive bumps 402, the microphone packaging structure 900′ can be directly mounted on a printed circuit board after dicing. In the embodiments shown in FIGS. 7-8, patterning of the sealing layer 308 and formations of the conductive layer 400 and the conductive bumps 402 are performed to the microphone packaging structure 900 prior to dicing thereof into the microphone packaging structure 900′, and the microphone packaging structure 900′ is then formed by performing a dicing process to microphone packaging structure 900.

The above exemplary microphone package structures 900′ have the following advantages.

1. There is no need for a cover in the microphone package structure, and a package size of the microphone package structure is thus reduced.

2. There is no need to form a chamber in the integrated circuit substrate, thus fabrication of the microphone package structure is easier and fabrication cost is thus reduced.

3. The microphone package structure is only formed as a two-layer stacked structure, and there is no need to form though silicon vias (TSVs) in the microphone package structure fabricated by a microelectricmechanical system (MEMS) technology, thus reducing fabricating costs and improving process reliabilities thereof.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A microphone package structure, comprising
an integrated circuit (IC) structure, comprising;
a first semiconductor substrate with opposite first and second surfaces; and
a first through hole disposed in and through the first semiconductor substrate;
and
a microphone structure disposed over the IC structure and electrically connected therewith, comprising:
a second semiconductor substrate with opposite third and fourth surfaces, wherein the third surface faces to the second surface of the first semiconductor substrate;
a second through hole disposed in and through the second semiconductor substrate;
an acoustic sensing device embedded in the second through hole and adjacent to the third surface; and
a sealing layer disposed over the fourth surface of the second semiconductor substrate, defining a back chamber with the sealing layer,
wherein the first through hole allows acoustic pressure waves to penetrate and pass therethrough to the acoustic sensing device.

2. The microphone package structure as claimed in claim 1, wherein the IC structure further comprises a plurality of conductive contacts and a plurality of first conductive layers, wherein the first conductive layers are disposed over the second surface of the first semiconductor substrate, and the conductive contacts penetrate the first semiconductor substrate to physically contact the first conductive layers.

3. The microphone package structure as claimed in claim 2, further comprising:
a second conductive layer disposed over the first surface of the first semiconductor substrate, physically contacting the conductive contacts; and
a bonding pad disposed over the second conductive layer.

4. The microphone package structure as claimed in claim 1, further comprising a plurality of bonding pads disposed over the second surfaces of the first semiconductor substrate and the third surfaces of the second semiconductor, respectively, wherein the bonding pads are aligned and physically in contact with each other, thereby forming electrical connections between the IC structure and the microphone structure.

5. The microphone package structure as claimed in claim 1, wherein the sealing layer partially covers the fourth surface of the second semiconductor substrate adjacent to the second through hole.

6. The microphone package structure as claimed in claim 1, wherein the sealing layer entirely covers the fourth surface of the second semiconductor substrate.

7. The microphone package structure as claimed in claim 1, wherein the acoustic sensing device comprises a membrane and a back plate with a plurality of acoustic holes formed therein.

8. The microphone package structure as claimed in claim 7, wherein the back plate with the plurality of acoustic holes formed therein of the acoustic sensing device is disposed at a place adjacent to the first through holes.

9. The microphone package structure as claimed in claim 1, wherein the sealing layer comprises conductive polymers or conductive metals.

10. A method for fabricating a microphone package structure, comprising:
providing an integrated circuit (IC) structure, comprising;
a first semiconductor substrate with opposite first and second surfaces; and
one or a plurality of first through holes separately disposed in and through the first semiconductor substrate;
providing a microphone structure over the IC structure and electrically connected therewith, comprising:
a second semiconductor substrate with opposite third and fourth surfaces, wherein the third surface faces to the second surface of the first semiconductor substrate;
a second through hole disposed in and through the second semiconductor substrate;
an acoustic sensing device embedded in the second through hole and adjacent to the third surface; and
a sealing layer disposed over the fourth surface of the second semiconductor substrate, defining a back chamber with the sealing layer;
and
performing a bonding process to bond the first bonding pads of the IC structure with the second bonding pads of the microphone structure, thereby forming the microphone package structure.

11. The method as claimed in claim 10, wherein the bonding process is a conductive glue adhesion or an eutectic welding adhesion bonding process.

12. The method as claimed in claim 10, wherein the IC structure further comprises a plurality of conductive contacts and a plurality of first conductive layers, wherein the first conductive layers are disposed over the second surface of the first semiconductor substrate, and the conductive contacts penetrate the first semiconductor substrate and physically contact the first conductive layers.

13. The method as claimed in claim 12, further comprising:
a second conductive layer disposed over the first surface of the first semiconductor substrate, physically contacting the conductive contacts; and
a conductive bump disposed over the second conductive layer.

14. The method as claimed in claim 10, wherein the sealing layer partially covers the fourth surface of the second semiconductor substrate adjacent to the second through hole.

15. The method as claimed in claim 10, wherein the sealing layer entirely covers the fourth surface of the second semiconductor substrate.

16. The method as claimed in claim 10, wherein the acoustic sensing device comprises a membrane and a back plate with a plurality of acoustic holes formed therein.

17. The method as claimed in claim 16, wherein the back plate with the plurality of acoustic holes formed therein of the acoustic sensing device is disposed at a place adjacent to the first through holes.

18. The method as claimed in claim 10, wherein the sealing layer comprises conductive polymers or conductive metals.

19. The method as claimed in claim 10, wherein the first and second semiconductor substrates are wafer-level substrates, and the method further comprises performing a dicing process to separate the microphone package structure into a plurality of chip-level microphone package structures.
